(19) United States
(12) Patent Application Publication
(10) Pub. No.: US 2005/0242895 A1
(43) Pub. Date: Nov. 3, 2005

(54) Voltage-controlled oscillator with four terminal varactors

(76) Inventor: Younes Lotfi, Colorado Springs, CO (US)

Correspondence Address: CHRISTIE, PARKER & HALE, LLP, PO BOX 7068, PASADENA, CA, 91109-7068, US

(21) Appl. No.: 10/834,442

(22) Filed: Apr. 28, 2004

(51) Int. Cl. H03B 5/00

(52) U.S. Cl. 331/177 V

(57) ABSTRACT

A voltage-controlled oscillator (VCO) capable of controlling VCO gain magnitude, VCO frequency tuning range and gain linearity, which in turn allows the loop bandwidth of a phase-locked loop to be controlled electrically with the VCO circuit and increases the frequency tuning range for the VCO circuit. An embodiment includes a voltage-controlled oscillator comprising an LC tank having a plurality of varactors, each of the plurality of varactors having four terminals. At least one of the terminals is coupled to a first control signal and one of the terminals is a substrate terminal coupled to a second control signal.

### BACKGROUND OF THE INVENTION

The present invention relates generally to voltage-controlled oscillators, and more particularly to LC tank voltage-controlled oscillators.

A phase-locked loop (PLL) is a component widely used in wireless communication systems. A PLL generates a clock signal using a received data stream. The clock signal has the same phase and frequency (or multiple of the frequency) as the received data stream. For example, in a receiving unit of a digital data communication system, to recover transmitted data, a PLL in the receiving unit synchronizes an internal clock of the receiving unit to the frequency and phase of the received data. Clock multiplication units, frequency synthesizers and clock recovery circuits are common applications of a PLL.

An oscillator, such as a voltage-controlled oscillator (VCO) is generally used in PLL's to generate a controllable clock signal. A VCO has an oscillation frequency controllable by the application of a control voltage. Ideally VCO generates a periodic output whose frequency is a linear function of the control voltage. Also ideally, the frequency tuning range of a VCO is sufficiently large to provide a clock signal over a wide range of frequencies, and to account for variations, such as temperatures, power supply variations and process parameter variations.

In high frequency applications, a VCO typically includes an LC tank with varactors. Varactors provide an adjustable capacitance, which enables adjustment of the oscillator frequency. Commonly used varactors are either two terminal PN junction diodes or three-terminal MOSFET or MESFET devices. In a two-terminal P/N node, the change in capacitance between the anode terminal and the cathode terminal is caused by changing the control voltage, V_{control}, applied to a P/N diode. For three-terminal MOSFET or MESFET devices, the change in capacitance between the gate terminal and the substrate is caused by changing the control voltage, V_{control}, applied to the source and drain terminals. In these types of varactors, however, the capacitance tuning is limited due to fixed capacitance such as side-wall capacitance and parasitic PN junction capacitance. Limited capacitance tuning results in a smaller tuning range and poor linearity of frequency relative to the control voltage.

### SUMMARY OF THE INVENTION

The present invention provides a VCO capable of controlling VCO gain magnitude and gain linearity, which in turn allows the loop bandwidth of the PLL to be controlled electrically with the VCO circuit and increases the frequency tuning range for the VCO circuit.

In one aspect, the invention provides a voltage-controlled oscillator comprising an LC tank having a plurality of varactors. Each of the plurality of varactors has four terminals, where at least one of the terminals is coupled to a first control signal and one of the terminals is a substrate terminal coupled to a second control signal.

In a further aspect, the invention provides a voltage-controlled oscillator comprising an LC tank having a plurality of varactors. Each of the varactors has a first voltage potential difference between a gate and a source-drain and a second voltage potential difference between a substrate and the source-drain. The first voltage potential difference and the second voltage potential difference are adjustable to provide a desired capacitance.

In a further aspect, the invention provides a phase locked loop comprising a voltage controlled oscillator comprising an LC tank having at least one varactor. Each varactor has four terminals, where at least one of the terminals is coupled to a first control signal and one of the terminals is a substrate terminal coupled to a second control signal. The first control signal and the second control signal are different signals creating a voltage potential difference across the varactor.

In a further aspect, the invention provides a phase locked loop comprising a phase detector generating an phase error signal based on a comparison between an output feedback signal and an input reference signal. A voltage-controlled oscillator receives a correction signal derived from the phase error signal and determines a first control signal from the correction signal. The voltage-controlled oscillator also receives a second control signal derived by an adjustable voltage generator. The voltage-controlled oscillator comprises an LC tank having a plurality of varactors. Each of the plurality of varactors has four terminals, where at least one of the terminals is coupled to the first control signal and one of the terminals is a substrate terminal coupled to the second control signal. The voltage-controlled oscillator generates a modified output feedback signal from the control signals to adjust the output feedback signal to the phase detector.

In a further aspect, the invention provides a method of controlling a frequency tuning range of a voltage-controlled oscillator with a plurality of four terminal varactors. The method comprises applying a first control signal to at least one of the terminals of the plurality of four terminal varactors and applying a second control signal to a substrate terminal of the plurality of four terminal varactors. The method also comprises modifying the first control signal to modify the frequency of an output signal and modifying the second control signal to vary the effect of the first control signal on the frequency of the output signal.

These and other aspects of the invention are more fully appreciated upon review of this disclosure including the associated figures.

### BRIEF DESCRIPTION OF THE DRAWINGS

In the drawings, like reference characters generally refer to the same parts throughout the different drawings.

FIG. 1 illustrates an electrical schematic of an embodiment of an LC tank-based VCO in accordance with aspects of the invention.

FIG. 2 illustrates a block diagram of a phase-locked loop (PLL) constructed in accordance with aspects of the invention.

FIG. 3 illustrates a block diagram of a VCO in the PLL of FIG. 2 constructed in accordance with aspects of the invention.

FIG. 4 illustrates capacitance vs. V_{applied} measured at various substrate voltage (V_{sub}) settings in accordance with some aspects of the invention.

FIG. 5 illustrates VCO frequency tuning measured at various substrate voltage (V_{sub}) settings in accordance with some aspects of the invention.

FIG. 6 illustrates VCO gain calculated from the frequency tuning simulations of FIG. 5.

FIG. 7 illustrates capacitance vs. V_{applied} measurements at various substrate voltage (V_{sub}) settings in accordance with some other aspects of the invention.

FIG. 8 illustrates VCO frequency tuning measurements at various substrate voltage (V_{sub}) settings in accordance with some other aspects of the invention.

FIG. 9 illustrates VCO gain calculated from the frequency tuning curves of FIG. 8.

### DETAILED DESCRIPTION OF THE INVENTION

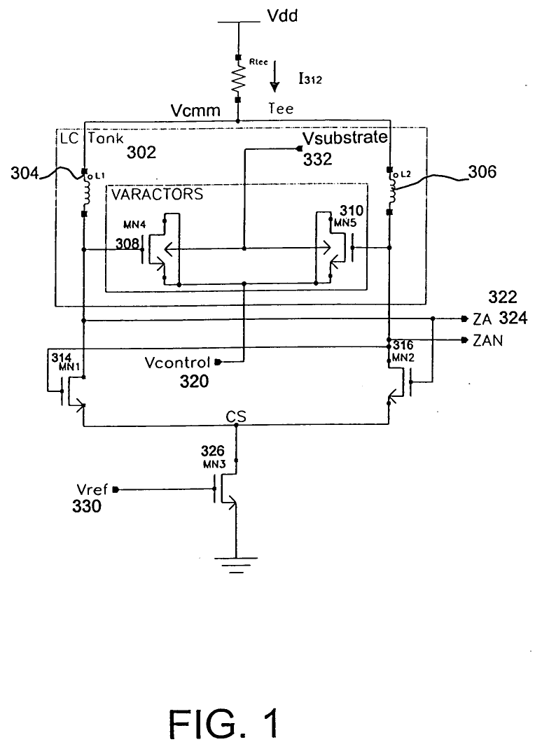

FIG. 1 illustrates an electrical schematic of an embodiment of an LC tank-based VCO having four terminal varactors in accordance with aspects of the invention. In one embodiment, a VCO includes an LC tank 302 having inductors L1 304 and L2 306 and varactors MN4 308 and MN5 310. The varactors provide variable capacitance. Input end of the inductors L1 304 and L2 306 are coupled to a resistor, Rₜₑₑ, and a voltage source, V_{dd}.

In the embodiment of FIG. 1, the varactors are four terminal N-channel MOSFET devices, MN4 308 and MN5 310, each having a gate terminal, a drain terminal, a source terminal and a substrate (also referred to as bulk) terminal. With respect to MN4 308, the gate terminal is coupled to the output end of the inductor L1 304. The gate terminal is also coupled to an output node ZA 322 and the drain terminal of an N-channel MOSFET device MN1 314. The drain and the source terminals of MN4 308 are coupled to a first control voltage V_{control} 320. In some embodiments, V_{control} is provided from external sources outside of an integrated circuit or a chip. In some other embodiments, V_{control} is provided internally by the PLL. The substrate terminal is coupled to a second control voltage, V_{substrate} 332. In some embodiments, V_{substrate} is provided from external sources outside of the integrated circuit or the PLL chip. In some other embodiments, V_{substrate} is provided internally within the integrated circuit or the PLL chip.

The varactors MN4 308 and MN5 310 are in a mirror image from each other. Thus, with respect to the varactor MN5 310, the gate terminal of MN5 310 is coupled to the output end of the inductor L2 306. The gate terminal is coupled to an output node ZAN 324 and the drain terminal of an N-channel MOSFET device MN2 316. Similarly, the drain and the source terminals of MN5 310 are coupled to V_{control} 320. The substrate terminal of MN5 310 is also coupled to V_{substrate} 332. Frequency tuning is accomplished by modulating the control signals, V_{control} and V_{substrate}.

Still referring to FIG. 1, the DC common mode voltage, denoted as V_{cmm}, for the LC tank 302 is set by the voltage source V_{dd} and the voltage drop across Rₜₑₑ. More specifically, V_{cmm} is calculated by:
V_{cmm}=V_{dd}−(Rₜₑₑ*I₃₁₂).
V_{cmm} is provided to the input ends of the inductors L1 304 and L2 306.

The frequency of oscillation is inversely related to the square root value of inductance and capacitance in the VCO. The inductance is derived from the inductors L1 and L2 of the LC tank. The capacitance is derived from the varactors MN4 and MN5, and other transistors driving the varactors. Due to the inverse relationship between the frequency and the capacitance, the frequency of oscillation can be adjusted by varying the capacitance of the VCO. More specifically, the frequency of oscillation, denoted as f, is calculated by:
f=1/(2529 \sqrt{LCeq}), where C_{eq}=Cᵥₐᵣ+C_{fix}.
Cᵥₐᵣ is the varactor capacitance and C_{fix} is the fixed capacitances due to interconnect wires and gate capacitance of the other N-channel MOSFET devices MN1 314 and MN2 316. Since the values of L and C_{fix} generally remain fixed, the frequency can be increased by reducing the varactor capacitance and the frequency can be reduced by increasing the varactor capacitance.

The size of an N-channel MOSFET device MN3 326, the drain of which is coupled to the sources of MN1 314 and MN2 316, and Vref 330, supplying voltage to the gate of the MN3 326, set the current for MN1 314 and MN2 316. The voltage potential difference between gate and source-drain and voltage potential difference between substrate and source-drain set the capacitance value of the varactor devices, MN4 308 and MN5 310. The voltage applied to the gate of MN4 308 and MN5 310 is fixed by the DC common mode voltage Vcmm. Thus, by varying the control voltages (V_{control} 320 and V_{substrate} 332), the capacitance of the MN4 308 and MN5 310 varies. As the V_{control} 320 becomes more positive with respect to Vcmm, the MOSFET varactor operates in the accumulation region where the capacitance value increases. As the V_{control} 320 becomes more negative with respect to Vcmm, the MOSFET varactor operates in the depletion region and results in inversion where varactor capacitance becomes smaller. Total varactor capacitance can be expressed as:
Cₜₒₜ=Cᵥₐᵣ+C_{fix}
Cᵥₐᵣ is the variable capacitance. C_{fix}=C_{sw}+Cₚₙ is the fixed capacitance, which is the sum of side-wall capacitance, C_{sw}, and parasitic PN junction capacitance, Cₚₙ. Cₘᵢₙ is the minimum value of Cₜₒₜ obtained with V_{substrate} 332 set at 0 volt. Cₘₐₓ is the maximum value of Cₜₒₜ obtained with V_{substrate} 332 set at 0 volt.

The second control voltage V_{substrate} 332 modulates the parasitic PN junction capacitance, Cₚₙ, values further. When V_{substrate} is at its most negative potential and the varactor is in the inversion region, then the two parasitic PN junction capacitance of substrate-source and substrate-drain are fully reverse biased. The capacitance of parasitic PN junctions, Cₚₙ, reduces the fixed capacitance and thus reduces the total capacitance value Cₜₒₜ further, allowing the value of Cₜₒₜ to be less than the value of Cₘᵢₙ, the minimum capacitance value with Vsubstrate set at 0 volt. Since the maximum VCO upper frequency is inversely proportional to Cₘᵢₙ, the reduced minimum total capacitance value Cₘᵢₙ increases the VCO upper frequency range.

However, the total varactor capacitance reduction due to parasitic PN junctions in the accumulation region is less than the inversion region. This is because the parasitic PN junctions are not reverse biased in this region. Thus the maximum value Cₜₒₜ allowed with both control voltages, Vcontrol and Vsubstrate, is slightly less than the value of Cmax with substrate voltage control at 0 volt (V_{substrate}=0 v). As a result, the total capacitance tuning range Cₜᵤₙ=Cₘₐₓ−Cₘᵢₙ is increased as the substrate control voltage becomes more negative and accordingly reduces the value of Cmin even further. Increase in the capacitance tuning range results in a larger VCO frequency tuning range. Thus modulating the V_{substrate} from 0 voltage to some negative voltages increases the capacitance tuning range and the frequency tuning range.

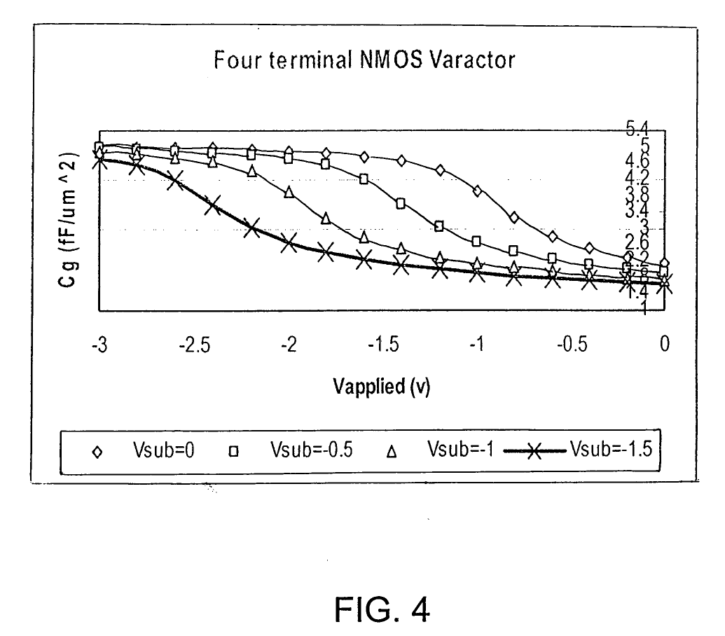

Moreover, by applying a negative potential (V_{substrate} 332) across the substrate of the varactor and varying the V_{substrate} 332 settings, the linear range of the capacitance can be adjusted. For example, as illustrated in FIG. 4, applying 0V to V_{substrate} 332, the capacitance is linear when V_{applied} is in the range of −1.3 to 0V. V_{applied} is the voltage applied between the gate and source/drain of the four terminal varactors. V_{applied} is expressed as V_{applied}=V_{cmm}−V_{control}. Applying −0.5 to V_{substrate} 332, the capacitance is linear when V_{applied} is in the range of −1.8 to 0V. Applying −1V to V_{substrate} 332, the capacitance is linear when V_{applied} is in the range of −2.3V to 0V. Applying −1.5V to V_{substrate} 332, the capacitance is linear when V_{applied} is in the range of −2.8 to 0V.

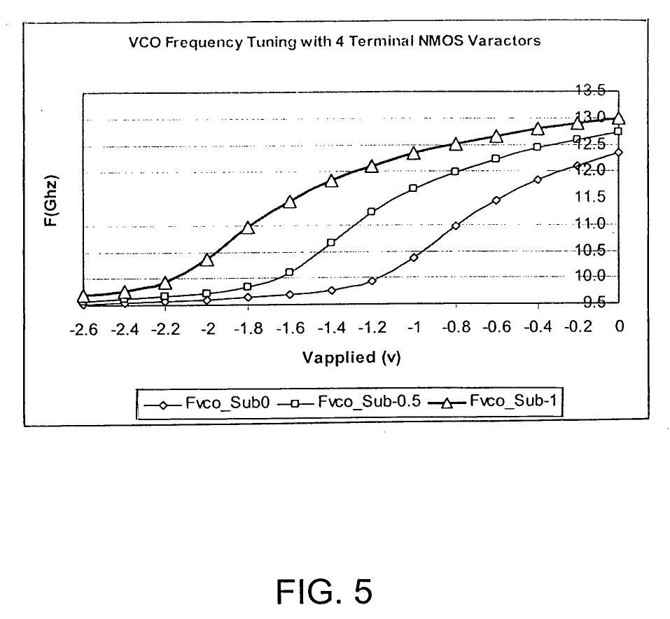

Furthermore, the frequency tuning range, in particular the linearity of the frequency tuning range, can be adjusted by varying the Vsubstrate 332 settings. For example, as illustrated in FIG. 5, applying 0V to V_{substrate} 332, the frequency tuning range is linear when V_{applied} is in the range of −1.2 to 0V. Applying −0.5V to V_{substrate} 332, the frequency tuning range is linear when V_{applied} is in the range of −1.6 to 0V. Applying −1V to V_{substrate} 332, the frequency tuning range is linear when V_{applied} is in the range of −2 to 0V.

Thus, in one embodiment, when V_{applied} reaches the expected end of the linear frequency tuning range for a given V_{substrate}, V_{substrate} is changed to extend the linear frequency tuning range for the VCO. Referring back to FIG. 5, in one example, if V_{substrate} is initially set to 0V and the VCO reaches the expected end of the linear tuning range, which is 12.4 GHz, the VCO switches V_{substrate} to −0.5V to extend the tuning range to 12.7 GHz. After reaching the expected end of 12.7 GHz, the VCO may switch V_{substrate} to −1V to extend the tuning range to 13.0 GHz if needed.

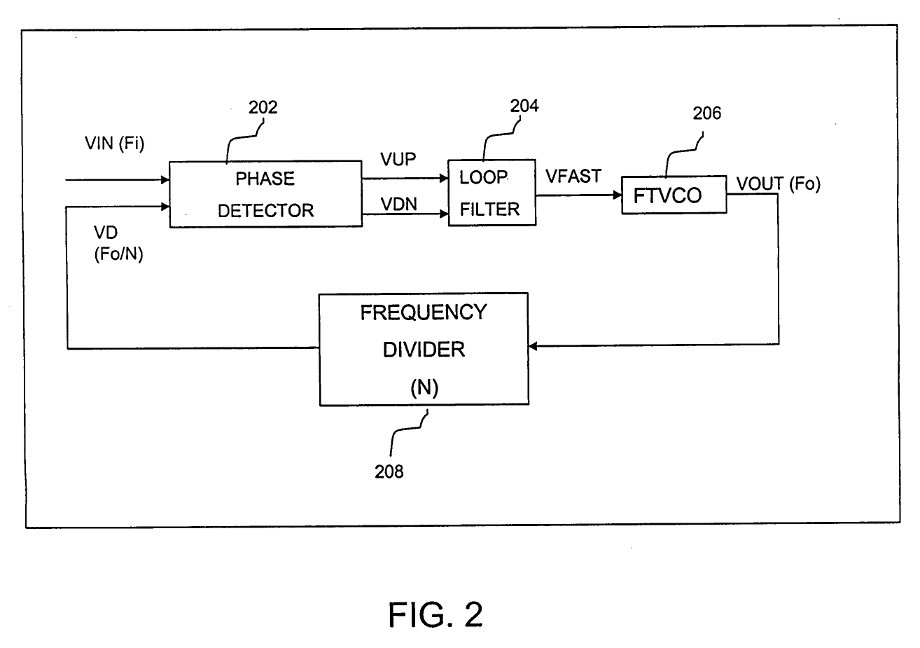

FIG. 2 illustrates an embodiment of a PLL comprising four-terminal varactors constructed in accordance with aspects of the invention. The PLL of FIG. 2 comprises a phase detector (PD) 202, a loop filter 204, a four-terminal varactor voltage-controlled oscillator (FTVCO) 206 and a frequency divider 208. The PD 202 receives incoming signal, V_{IN}, from a transmitter (not shown) and a feedback signal V_{D} from the frequency divider 208 of the PLL as inputs. The PD 202 outputs an up pulse signal, denoted as V_{UP}, and a down pulse signal, denoted as V_{DN}. A loop filter 204 receives V_{UP} and V_{DN} and outputs a correction signal, denoted as V_{FAST}. A four-terminal varactor VCO (FTVCO) 206 receives the V_{FAST} signal and outputs V_{OUT} (Fₒ). The frequency of Vₒᵤₜ, denoted as Fₒ, from the FTVCO is divided by a predetermined frequency dividing rate N (where N is a positive integer) by the frequency divider 208. The divided output voltage, now denoted as the feedback signal V_{D} is then fed back to the input of the phase detector 202. When the output frequency, Fₒ, is equal to Fᵢ multiplied by N, the PLL system is locked to the frequency of the incoming signal, V_{IN}.

An input signal V_{IN} (Fᵢ) is a signal containing digital clock or data at a frequency Fᵢ fixed by a transmitting device (not shown). When the phase detector 202 of a PLL in a receiver receives V_{IN}, the phase detector circuit 202 compares the frequency and phase of the feedback signal V_{D} with the frequency and phase of the incoming signal V_{IN}. Based on the comparison of the two signals, the phase detector 202 determines if the frequency of the oscillator FTVCO 206 should be increased or decreased.

For example, based on the comparison of the two signals, the phase detector 202 generates a phase error signal V_{UP} or V_{DN} that has a duration proportional to the phase difference detected. The phase error signal pushes the FTVCO 206 to achieve the frequency of the output signal V_{OUT} to be in phase with the input V_{IN} signal (also referred to as the reference signal) and to have a frequency equal to N times the frequency of V_{IN}. More specifically, the phase detector 202 sets the up signal, V_{UP}, to high, and the down signal, V_{DN} to low, when the feedback signal V_{D} lags the reference signal V_{IN}. In one implementation, V_{UP} is a pulse signal having a duration that is proportional to the phase difference and causes the FTVCO 206 to increase the frequency of the output signal V_{OUT}. If, on the other hand, the PD 202 determines that the feedback signal V_{D} leads the reference signal V_{IN}, the PD 202 sets V_{DN} to high and V_{UP} to low. The V_{DN} pulse has a duration that is proportional to the phase difference and causes the FTVCO 206 to reduce the frequency of the output signal V_{OUT}.

The loop filter 204 is a low pass filter that suppresses the high frequency components in the signals V_{UP} and V_{DN}. The loop filter 204 is also an integrator that integrates the received pulse signals and generates a correction signal V_{FAST}.

The four-terminal VCO (FTVCO) 206 circuit is a free running oscillator in which the frequency of the output signal V_{OUT} is adjusted through a first control voltage, V_{control} derived from the detected outputs V_{UP} and V_{DN} of the phase detector 202, and a second control voltage, V_{substrate}, driven by an adjustable voltage generator. In one embodiment, the adjustable voltage generator is operated manually as needed. In other embodiment, the adjustable voltage generator is programmed to automatically provide appropriate levels of voltage to the substrate of the varactors. In one embodiment, the adjustable voltage generator is located within the PLL. In other embodiments, the adjustable voltage generator is provided outside of the PLL circuit. In one embodiment, the V_{control} and V_{substrate} signals are different signals creating a voltage potential difference across the varactors. In some embodiments, the V_{control} and V_{substrate} signals are independently controlled.

In one embodiment, the linear range of capacitance of the varactor with respect to the V_{control} 320 signals can be adjusted by varying the V_{substrate} 332 settings. For example, in one implementation the linear range of capacitance with respect to the Vcontrol 320 increases as the V_{substrate} becomes more negative. In another embodiment, the linearity of the frequency tuning range of the FTVCO with respect to the V_{control} 320 can be adjusted by varying the V_{substrate} 332 settings. In some embodiments, the tuning range of the FTVCO 206 can be extended by varying the V_{substrate} 332 settings. In some other embodiments, the maximum oscillation frequency of the FTVCO 206 is greater for the same V_{control} 320 when the V_{substrate} 332 is more negative with a greater magnitude. The FTVCO 206 adjusts frequency until the frequency of the output signal V_{OUT} is in phase with the input V_{IN} signal and the frequency is equal to N times the frequency of V_{IN}. Moreover, in yet another embodiment, the gain of FTVCO 206 can be adjusted linearly with respect to V_{substrate} 332.

The gain of the FTVCO 206 is also directly related to the tuning frequency range and inversely related to the control voltage, V_{control} 320. More specifically, VCO gain, K_{VCO}, is defined as the maximum tuning frequency range, which is the difference between the maximum frequency and the minimum frequency of oscillation in the FTVCO, divided by the maximum variation, or entire range, in the control voltage, V_{control} 320:
K_{VCO}=(Fₕ−Fₗ)/(Vₘₐₓ −Vₘᵢₙ).

In some embodiments the entire range of the control voltage is limited to the range of voltage over which a relatively small change in the control voltage results in a relatively small change in oscillator frequencies.

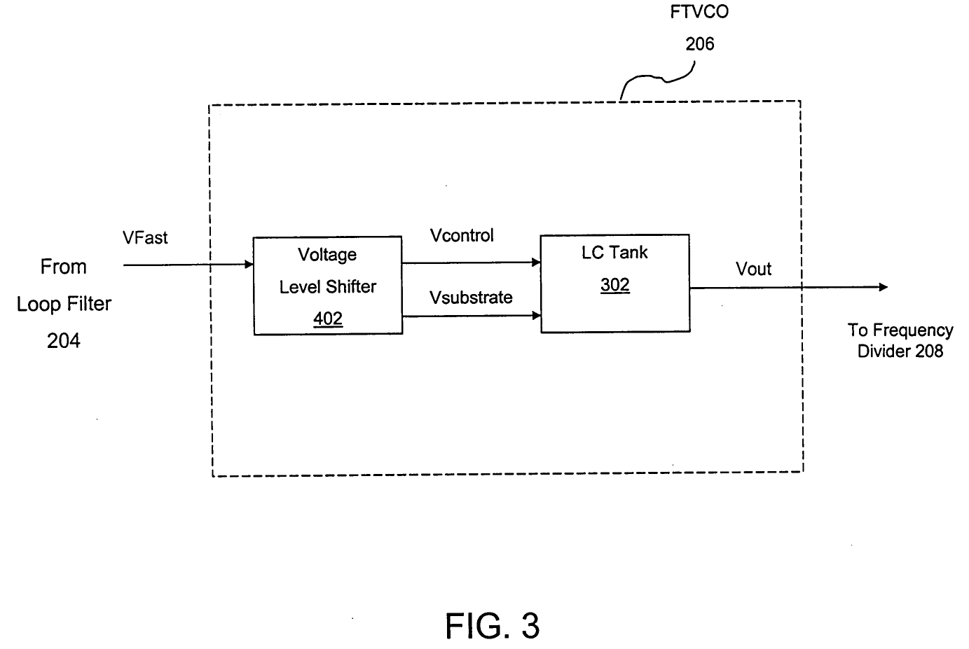

In one embodiment, the PLL of FIG. 2 comprises a four-terminal varactor FTVCO 206 as illustrated in FIG. 1. Referring to FIG. 3, in some embodiments, the FTVCO 206 comprises a voltage level shifter 402 and a VCO, for example an LC tank 302 with the VCO circuitry as shown in FIG. 1. In some embodiments, the voltage level shifter 402 is located outside of the FTVCO 206. In these embodiments, the voltage level shifter 402 may be located inside of the loop filter 204 of FIG. 2. In some instances, the voltage level shifter 402 may be a stand-alone circuitry that is interposed between the loop filter 204 and the FTVCO 206. In the example of FIG. 3, the voltage level shifter 402 receives the V_{FAST} signal from the loop filter 204 and shifts the V_{FAST} signal to a signal level appropriate for the Vcontrol 320. The shifted V_{FAST} signal is then applied to the V_{control} input 320 of FIG. 1.

Referring again to FIG. 2, the FTVCO 206 generates the output signal V_{OUT} having a frequency set by the control voltages V_{control} and V_{substrate}, and the frequency divider 208 generates the feedback signal V_{D} from the output signal V_{OUT}.

In operation, if the frequency, Fₒ/N, of the voltage V_{D} is higher than V_{IN} (Fᵢ), then the V_{control} signal 320 is adjusted to be more positive. Increased V_{control} 320 increases Cᵥₐᵣ, which in turn increases C_{eq} and decreases the frequency, f, of the FTVCO. In a PLL circuit, the FTVCO 206 (as shown in FIG. 3) will continue with the frequency correction operation until the frequency and the phase of the V_{D} and received input signal, V_{IN}, are equal.

If, on the other hand, the frequency of the V_{D} is slower than the frequency of the received input signal V_{IN} at the input of the phase detector 202, V_{control} 320 is adjusted to be more negative. The reduced V_{control} 320 decreases Cᵥₐᵣ, which in turn reduces C_{eq}, and increases the frequency, f, of the FTVCO. In one embodiment, if V_{control} 320 reaches the upper end of the frequency tuning range, the V_{substrate} 332 signal is applied to extend the upper end of the frequency range. For example, by applying a negative voltage to V_{substrate} 332, the upper end of the tuning range can extend. By increasing the magnitude of the negative voltage applied to V_{substrate} 332, the upper end of the tuning range can extend even further.

In some embodiments, the amount of V_{substrate} 332, applied to the substrate terminal of the varactors MN4 308 and MN5 310, controls tuning range, gain magnitude and gain linearity of the FTVCO. For example, the linear range of capacitance of the four-terminal varactor relative to the V_{control} 320 signals can be adjusted by varying V_{substrate} 332 settings. In one implementation, the linear range of capacitance with respect to the V_{control} signals increases as the V_{substrate} becomes more negative. In another example, the linearity of the frequency tuning range with respect to the V_{control} 320 of the FTVCO can be adjusted by varying the V_{substrate} 332 settings. The tuning range of the FTVCO can also be extended by varying the V_{substrate} 332 settings. In one implementation, the maximum oscillation frequency of the FTVCO is greater for the same V_{control} 320 as the V_{substrate} 332 becomes more negative with a greater magnitude. Moreover, in yet another implementation, the gain of the FTVCO 206 can be adjusted linearly with respect to the V_{substrate} 332 signals.

FIG. 4 illustrates capacitance v. voltage (CV) measurements of a four-terminal NMOS varactor at various V_{substrate} 332 settings constructed in accordance with aspects of the invention. More specifically, FIG. 4 illustrates gate capacitance v. V_{applied} of a four terminal NMOS varactor at four different substrate voltage (V_{substrate} 332) settings, 0V, −0.5V, −1V and −1.5V. Although these four setting are used in this illustrative embodiment, any amount of V_{substrate} 332 that allows a VCO to attain the desired tuning range, gain magnitude and gain linearity CV may be applied. CV characteristics of a MOSFET is a function of their channel doping and the PN junctions formed between the source, drain and substrate terminals.

As illustrated in FIG. 4, for all four V_{substrate} settings, the gate capacitance decreases as V_{applied} becomes more positive. As stated before, V_{applied} is expressed as:
V_{applied}=V_{cmm}−V_{control} (v).
However, the linear range of capacitance is different for each V_{substrate} setting. Applying 0V to V_{substrate} 332, the capacitance is linear when V_{applied} is in the range of −1.3 to 0V. Applying −0.5 to V_{substrate} 332, the capacitance is linear when V_{applied} is in the range of −1.8 to 0V. Applying −1V to V_{substrate} 332, the capacitance is linear when V_{applied} is in the range of −2.3V to 0V. Applying −1.5V to V_{substrate} 332, the capacitance is linear when V_{applied} is in the range of −2.8 to 0V.

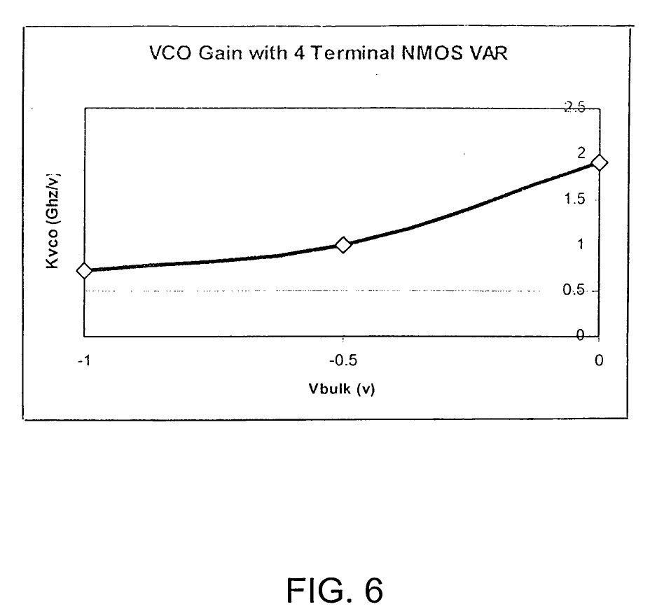

Moreover, the rate of varactor capacitance change with respect to V_{applied} across a varactor is different for each V_{substrate} 332 setting at 0, −0.5, −1, and −1.5 volt. As V_{substrate} 332 becomes more negative, e.g., from 0to −1.5 volt, the rate of gate capacitance with V_{applied} applied across the varactor decreases. Such differences in the CV rates effect the frequency tuning range and gain for a VCO, as illustrated in FIGS. 5 and 6.

FIG. 5 depicts VCO frequency tuning curves of a VCO having four terminal NMOS varactors (FTVCO) at various substrate voltage (V_{substrate}) 332 settings in accordance with aspects of the invention. In the illustrative embodiment, V_{substrate} 332 is set at 0 v, −0.5V, and −1V. Although these three setting are used in this illustrative embodiment, any amount of V_{substrate} 332 that allows a FTVCO to attain the desired tuning range, gain magnitude and gain linearity may be applied.

As illustrated in FIG. 5, the value of the maximum VCO frequency is greater when V_{substrate} 332 is more negative with a greater magnitude. For example, when V_{substrate} 332 is at −1V, the maximum VCO frequency is 13.0 GHz and V_{applied} (V_{cmm}−V_{control} 320) is 0V, whereas when V_{substrate} 332 is at 0V, the maximum VCO frequency is 12.4 GHz and V_{applied}(V_{cmm}−V_{control} 320)is also at 0V. The minimum VCO frequencies are similar for all three V_{substrate} settings, ranging around 9.5 GHz when V_{applied} (V_{cmm}−V_{control} 320) is −2.6V. Thus the VCO frequency tuning range, which is the difference between the maximum frequency and the minimum frequency of oscillation in the FTVCO, increases as V_{substrate} 332 becomes more negative with a greater magnitude. Furthermore, the linearity of the frequency tuning range can be adjusted by varying the V_{substrate} 332 settings. Applying 0V to V_{substrate} 332, the frequency tuning range is linear when V_{applied} is in the range of −1.2 to 0V. Applying −0.5V to V_{substrate} 332, the frequency tuning range is linear when V_{applied} is in the range of −1.6 to 0V. Applying −1V to V_{substrate} 332, the frequency tuning range is linear when V_{applied} is in the range of −2 to 0V.

FIG. 6 illustrates the FTVCO gain magnitude in relation with the various V_{substrate} settings of FIG. 5. Applying the equation for the gain magnitude, K_{vco}=(Fₕ−Fₗ)/(Vₘₐₓ−Vₘᵢₙ), from the discussion of FIG. 2, the gain magnitude has been calculated for all three V_{substrate} settings, and connected to show VCO gain control and adjustability. As illustrated in FIG. 6, FTVCO gain can be controlled by adjusting the V_{substrate}. Thus, in some embodiments, four terminal varactors 308 and 310 of FIG. 1 control the frequency tuning range, VCO gain and linearity of FTVCO gain by varying the magnitude of the second control voltage, V_{substrate} 332, applied to the substrate terminal of the varactors.

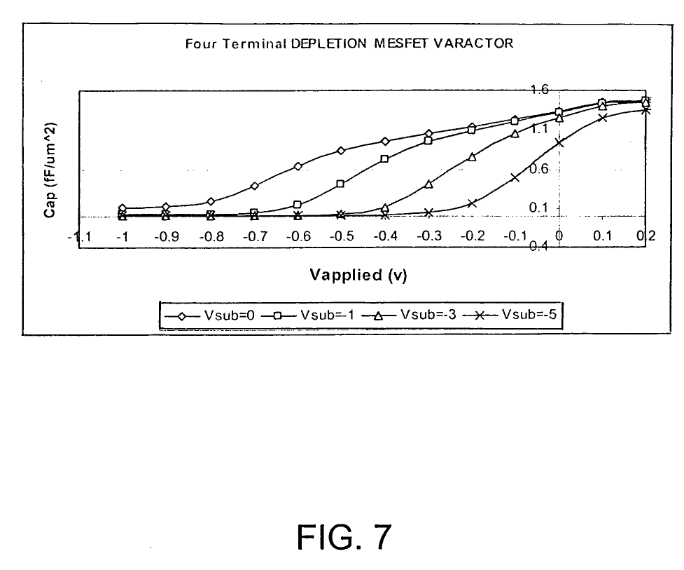

In some other embodiments, the present FTVCO circuit is implemented in GaAs technology. In GaAs technology, four terminal MESFET varactors are used in place of the MOSFET varactors MN4 308 and MN5 310. The substrate terminal of each MESFET varactors is similarly coupled to the V_{substrate} 332 to control the magnitude and linearity of FTVCO gain. FIG. 7 illustrates CV simulations of a four-terminal MESFET varactor at four different substrate voltage, V_{substrate} 332, settings in accordance with aspects of the invention. Referring to FIG. 7, the rate of gate capacitance of a four-terminal MESFET varactor with respect to V_{cmm}−V_{control} 320 (referred to as Vapplied (v) in FIG. 7) is different for each V_{substrate} 332 settings, for example at 0, −1, −3, and −5V. Although these four setting are used in this illustrative embodiment, any amount of V_{substrate} 332 that allows a FTVCO to attain the desired tuning range, gain magnitude and gain linearity may be applied.

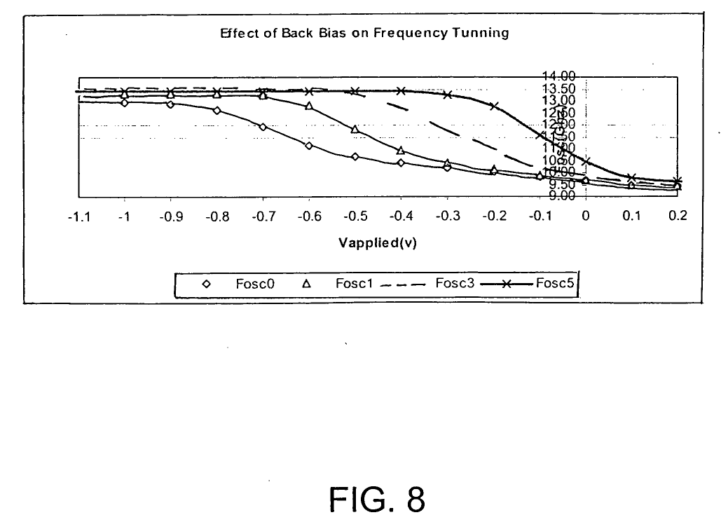

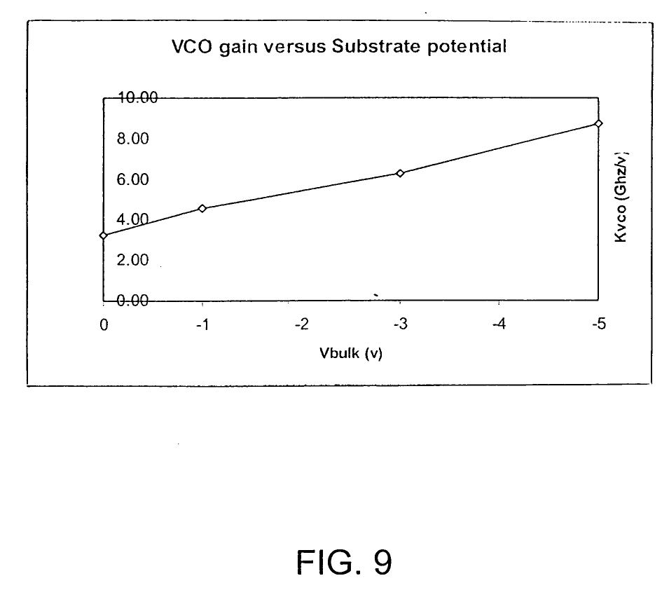

As illustrated in FIG. 7, for all four V_{substrate} 332 settings, the gate capacitance increases as V_{cmm}−V_{control} 320 (V_{applied}) becomes more positive. However, as V_{substrate} 332 becomes more negative, the rate of gate capacitance with respect to V_{cmm}−V_{control} 320 (V_{applied}) increases. More specifically, when V_{substrate} 332 is at −5V, the slope of the curve is steeper than the curves for the other V_{substrate} settings. Such differences in the CV rates effect the frequency tuning range and gain for a FTVCO, as illustrated in FIGS. 8 and 9.

FIG. 8 depicts VCO frequency tuning curves of a VCO having four-terminal MESFET varactors (FTVCO) at various substrate voltage (V_{substrate} 332) settings in accordance with aspects of the invention. The illustrative embodiment of FIG. 8 has V_{substrate} 332 set at four different settings: 0, −1, −3, and −5V. Although these four setting are used in this illustrative embodiment, any amount of V_{substrate} 332 that allows a FTVCO to attain the desired tuning range, gain magnitude and gain linearity CV may be applied.

As illustrated in FIG. 8, the value of the maximum VCO frequency is greater when V_{substrate} 332 is more negative. For example, when V_{substrate} 332 is at −5V, the maximum VCO frequency is 13.50 GHz and V_{cmm}−V_{control} 320 (V_{applied}) is −0.4V, whereas when V_{substrate} 332 is at 0V, the maximum VCO frequency is 12.90 GHz and V_{cmm}−V_{control} 320 (V_{applied} ) is at −0.9V. When V_{substrate} 332 is at −5V, the minimum VCO frequency is 9.6 GHz and V_{cmm}−V_{control} 320 (V_{applied}) is 0.2V, whereas when V_{substrate} 332 is at 0V, the minimum VCO frequency is 9.5 GHz and V_{cmm}−V_{control} 320 (V_{applied}) is at 0.2V. Thus the VCO frequency tuning range, which is the difference between the maximum frequency and the minimum frequency of oscillation in the FTVCO, increases as V_{substrate} 332 becomes more negative.

FIG. 9 illustrates the VCO gain magnitude in relation with the various V_{substrate} settings of FIG. 8. Applying the equation for the gain magnitude, K_{vco}=(Fₕ−Fₗ)/(Vₘₐₓ−Vₘᵢₙ), from the discussion of FIG. 2, the gain magnitude has been calculated for all four V_{substrate} settings and connected to show VCO gain control and adjustability. As illustrated in FIG. 9, FTVCO gain can be controlled by adjusting the V_{substrate}. Thus, in some embodiments, four terminal varactors 308 and 310 of FIG. 1 control the frequency tuning range, VCO gain and linearity of FTVCO gain by varying the magnitude of the second control voltage, V_{substrate} 332, applied to the substrate terminal of the varactors.

Although the invention has been described with respect to certain embodiments, it should be recognized that the invention includes the claims and their equivalents supported by this disclosure.

1. A voltage-controlled oscillator comprising an LC tank having a plurality of varactors, each of the plurality of varactors having four terminals, at least one of the terminals coupled to a first control signal and one of the terminals being a substrate terminal coupled to a second control signal.

2. The voltage-controlled oscillator of claim 1, wherein the first control signal is an adjustable control signal.

3. The voltage-controlled oscillator of claim 1, wherein the second control signal is an adjustable control signal.

4. The voltage-controlled oscillator of claim 1, wherein the first control signal is a first adjustable control signal and the second control signal is a second adjustable control signal.

5. The voltage-controlled oscillator of claim 1, wherein each varactor is an N-channel MOSFET.

6. The voltage-controlled oscillator of claim 5, wherein the first control signal has a varying magnitude.

7. The voltage-controlled oscillator of claim 6, wherein a fixed DC common mode voltage is applied to a gate and the first control signal is applied to a source and a drain of at least one of the plurality of varactors.

8. The voltage-controlled oscillator of claim 7, wherein the difference in voltage between the fixed common mode voltage and the first control signal ranges between −3 and 0 volts.

9. The voltage-controlled oscillator of claim 5, wherein the second control signal has a varying magnitude.

10. The voltage-controlled oscillator of claim 9, wherein the second control signal is a voltage signal between −1.5 and 0 volts.

11. The voltage-controlled oscillator of claim 1, wherein each varactor is a depletion MESFET.

12. The voltage-controlled oscillator of claim 11, wherein the first control signal has a varying magnitude.

13. The voltage-controlled oscillator of claim 12, wherein a fixed DC common mode voltage is applied to a gate and the first control signal is applied to a source and a drain of at least one of the plurality of varactors.

14. The voltage-controlled oscillator of claim 13, wherein the difference in voltage between the fixed common mode voltage and the first control signal ranges between −1.1 and 0.2 volts.

15. The voltage-controlled oscillator of claim 11, wherein the second control signal has varying magnitude.

16. The voltage-controlled oscillator of claim 15, wherein the second control signal is a voltage signal between −5 and 0 volts.

17. The voltage-controlled oscillator of claim 1, wherein the first control signal and the second control signal are different signals.

18. The voltage-controlled oscillator of claim 1, wherein the first control signal and the second control signal are independently controlled.

19. A voltage-controlled oscillator comprising an LC tank having a plurality of varactors, each of the varactors having a first voltage potential difference between a gate and a source-drain and a second voltage potential difference between a substrate and the source-drain, the first voltage potential difference and the second voltage potential difference being adjustable to provide a desired capacitance.

20. The voltage-controlled oscillator of claim 19 wherein the second voltage potential difference is driven by an adjustable control voltage with a varying magnitude.

21. A phase locked loop comprising:
a voltage controlled oscillator comprising an LC tank having at least one varactor, each varactor having four terminals, at least one of the terminals coupled to a first control signal and one of the terminals being a substrate terminal coupled to a second control signal, the first control signal and the second control signal being different signals creating a voltage potential difference across the varactor.

22. The phase locked loop of claim 21 wherein the second control signal is an adjustable control voltage with a varying magnitude.

23. A phase locked loop comprising:
a phase detector generating an phase error signal based on a comparison between an output feedback signal and an input reference signal;
a voltage-controlled oscillator receiving a correction signal derived from the phase error signal and determining a first control signal from the correction signal, the voltage-controlled oscillator receiving a second control signal derived by an adjustable voltage generator, the voltage-controlled oscillator comprising an LC tank having a plurality of varactors, each of the plurality of varactors having four terminals, at least one of the terminals coupled to the first control signal and one of the terminals being a substrate terminal coupled to the second control signal, the voltage-controlled oscillator generating a modified output feedback signal from the control signals to adjust the output feedback signal to the phase detector.

24. The phase locked loop of claim 23 wherein the second control signal is an adjustable control voltage with a varying magnitude.

25. The phase locked loop of claim 24, wherein the voltage-controlled oscillator comprises a voltage level shifter that shifts the correction signal to a signal level appropriate for the first control signal.

26. The phase locked loop of claim 23, wherein the first control signal and the second control signal are independently controlled.

27. The phase locked loop of claim 23, wherein the first control signal and the second control signal are different signals.

28. A method of controlling a frequency tuning range of a voltage-controlled oscillator with a plurality of four terminal varactors, the method comprising:
applying a first control signal to at least one of the terminals of the plurality of four terminal varactors;
applying a second control signal to a substrate terminal of the plurality of four terminal varactors;
modifying the first control signal to modify the frequency of an output signal; and
modifying the second control signal to vary the effect of the first control signal on the frequency of the output signal.
